(19) United States
(12) Patent Application Publication
(10) Pub. No.: US 2015/0070078 A1
(43) Pub. Date: Mar. 12, 2015

(54) CIRCUIT AND METHOD FOR CONDUCTING SOFT TURN-OFF OF A DRIVING CIRCUIT OF SEMICONDUCTOR SWITCHING DEVICE

(71) Applicant: HYUNDAI MOTOR COMPANY, Seoul (KR)

(72) Inventors: Kang Ho Jeong, Hwaseong (KR); Ki Jong Lee, Osan (KR); Jee Hye Jeong, Hwaseong (KR)

(73) Assignee: HYUNDAI MOTOR COMPANY, Seoul (KR)

(21) Appl. No.: 14/141,059

(22) Filed: Dec. 26, 2013

(30) Foreign Application Priority Data
Sep. 11, 2013 (KR) 10-2013-0108807

(51) Int. Cl. H01L 29/739; H03K 17/60

(52) U.S. Cl. CPC H01L 29/7393; H03K 17/60
USPC 327/478; 257/139

(57) ABSTRACT

A circuit for conducting soft turn-off includes a semiconductor switching device, a resistor and a sink pin. The second semiconductor switching device has a current inflow terminal connected to a current control terminal of a first semiconductor switching device, and a current outflow terminal connected to a ground. The resistor has a first terminal connected to the current inflow terminal of the second semiconductor switching device, and a second terminal connected to a current control terminal of the first semiconductor switching device. The sink pin applies a value lower than a previous applied value (i.e., a low value) to the current control terminal of the second semiconductor switching device.

### CROSS-REFERENCE TO RELATED APPLICATION

This application claims under 35 U.S.C. §119(a) the benefit of Korean Patent Application No. 10-2013-0108807 filed Sep. 11, 2013, the entire contents of which are incorporated herein by reference.

### BACKGROUND

(a) Technical Field

The present invention relates to a soft turn-off circuit disposed in a driving circuit of a semiconductor switching device.

(b) Background Art

With the development of an insulated gate bipolar transistor (IGBT) which can act as a large-capacity switching device, the development or application of a power conversion device or electric motor driving circuit has been widely pursued. The IGBT provides a rapid substitution for existing gate turn-off thyristors (GTOs), etc. In addition, the IGBT is also important because it provides greater functional stability and reliability of circuits for driving the IGBT. Among these circuits, there is required a circuit that effectively prevents damage to the device or occurrence of noise, caused by an excessive voltage or current change.

That is, as the technology of the IGBT develops, the driving technology of the IGBT for guaranteeing the reliability and lifespan of a system using the IGBT also has become important. Thus, the stability of a switching operation of the IGBT should be ensured, and a measure for preventing damage to the device or occurrence of noise, caused by an excessive voltage change (dv/dt) and an excessive current change (di/dt) when an operation for protecting the device and the system should be performed.

Generally, t IGBT failure is classified into an overcurrent situation in which current is excessively applied to a load, and an arm-short situation in which current is simultaneously conducted to arms of the IGBT so that the arms of the IGBT are short-circuited. In such a failure, a ‘gate board’ for controlling a gate signal of the IGBT senses a breakdown, and transmits an off signal as the gate signal in order to protect a module.

However, when the gate-off signal is abruptly cut off, the conduction current of the IGBT is suddenly changed, and therefore, an excessive voltage is generated. Said another way, the current change (di/dt) between collector and emitter terminals of the IGBT is increased, and therefore, Vce is excessive in this situation. In particular, if the peak value of Vce exceeds the internal voltage of the module, the module is damaged. In order to prevent such a problem, a technique such as ‘soft turn-off’ may be used.

FIG. 5 is a diagram showing a conventional circuit for protecting an IGBT, using an integrated circuit (IC). In the conventional circuit for conducting soft turn-off, terminals Vout and Soft-off of an exclusive driver IC 10 are connected to a gate terminal of the IGBT. The conventional circuit implements soft turn-off, using the exclusive driver IC 10, and hence the driver IC 10 should provide a soft turn-off function. If such a function does not exist, it is impossible to implement the soft turn-off function. The soft turn-off should be implemented according to a predetermined specification (Spec) of the exclusive driver IC 10, and therefore, it is difficult to control the time at which the soft turn-off is applied and the amount of sink current. In addition, the cost of the conventional circuit implements the soft turn-off, using the exclusive driver IC 10 is relatively expensive, thus increasing the total manufacturing cost of the conventional circuit is increased.

FIG. 6 is a diagram showing a conventional circuit which implements soft turn-off, using RC discharge. The circuit of FIG. 6 has an advantage in that a simple RC circuit can be implemented using a resistor 20 and a capacitor 30. However, when current is consumed at a gate terminal of an IGBT, the discharge time changes every time, and therefore, it is difficult to consistently control soft turn-off.

In addition, attributes of a sink pin, including the drain-source resistance inside the sink pin and the maximum amount of sink current, are different, and therefore, it is not easy to determine a turn-off time constant.

FIG. 7 is a graph showing a change in voltage between the collector and emitter terminals of the IGBT as the soft turn-off is implemented. Through the graph of FIG. 7, it can be seen that, if the voltage at the gate terminal of the IGBT is abruptly cut off, the peak voltage Vpeak of the IGBT increases to about 1360V. However, it can be seen that, if current at the gate terminal of the IGBT is slowly discharged due to the implementation of soft turn-off, the peak voltage Vpeak of the IGBT is reduced to 1280V.

### SUMMARY OF THE DISCLOSURE

The present invention provides a soft turn-off circuit which shows a constant soft turn-off characteristic. The present invention also provides a soft turn-off circuit having a simple structure in which the soft turn-off of an insulated gate bipolar transistor (IGBT) is possible, using an open drain type sink pin, a resistor and a transistor, without using any exclusive driver integrated circuit (IC). The present invention also provides a soft turn-off circuit which can facilitate the adjustment of a time constant, and provides a soft turn-off circuit in which the sink path in soft turn-off is provided using a PNP transistor, thereby obtaining a further raised current internal voltage.

In one aspect, the present invention provides a circuit for conducting soft turn-off, the circuit including: a second semiconductor switching device having a current inflow terminal connected to a current control terminal of a first semiconductor switching device, and a current outflow terminal connected to a ground; a resistor having a first terminal connected to the current inflow terminal of the second semiconductor switching device, and a second terminal connected to a current control terminal of the second semiconductor switching device; and a sink pin that applies a value lower than a previous set value (i.e., a “Low” value) to the current control terminal of the second semiconductor switching device.

In an exemplary embodiment, the second semiconductor switching device may be a PNP transistor, the current control terminal of the second semiconductor switching device may be a base terminal, the current inflow terminal of the second semiconductor switching device may be an emitter terminal, and the current outflow terminal of the second semiconductor switching device may be a collector terminal.

In some exemplary embodiments, the sink pin may be an open drain type sink pin or a general purpose input output (GPIO) port.

In still another exemplary embodiment, the first semiconductor switching device may be an IGBT, and the current control terminal of the first semiconductor switching device may be a gate terminal.

In another aspect, the present invention provides a method for conducting soft turn-off, the method including: changing an output of a sink pin into value lower than a previous set value (i.e., a “Low” value) when a failure occurs in a first semiconductor switching device; allowing, by the circuit, current flow toward the sink pin through a resistor between a current inflow terminal and a current outflow terminal of a second semiconductor switching device, to generate a voltage through the resistor; and allowing, by the circuit, the current accumulated in the current control terminal of the first semiconductor switching device to be discharged toward a ground through the current inflow terminal and the current outflow terminal of the second semiconductor switching device as the voltage is generated through the resistor.

In an exemplary embodiment, the first semiconductor switching device may be an IGBT, and the current control terminal of the first semiconductor switching device may be a gate terminal. The second semiconductor switching device may be a PNP transistor, the current control terminal of the second semiconductor switching device may be a base terminal, the current inflow terminal of the second semiconductor switching device may be an emitter terminal, and the current outflow terminal of the second semiconductor switching device may be a collector terminal. The sink pin may be an open drain type sink pin or a GPIO port.

Other aspects and exemplary embodiments of the invention are discussed infra.

As described above, the circuit for conducting soft turn-off has advantages as follows.

First, since the circuit for conducting soft turn-off can be implemented via using only the open drain type sink pin, the circuit can be implemented with the GPIO port provided in the general MICOM or CPLD without using any exclusive driver IC. Thus, it is possible to provide a circuit for conducting soft turn-off, which is independent on a gate IC.

Second, since the amount of sink current is controlled by a fixed bias voltage during turn-off, it is possible to provide a circuit having soft turn-off characteristics.

Third, the sink path of soft turn-off is provided using the PNP transistor, so that the voltage of the PNP transistor can be greater than the sink current internal voltage of a general IC, thereby providing a more stable solution than conventional circuits.

### BRIEF DESCRIPTION OF THE DRAWINGS

The above and other features of the present invention will now be described in detail with reference to certain exemplary embodiments thereof illustrated the accompanying drawings which are given hereinbelow by way of illustration only, and thus are not limitative of the present invention, and wherein:

FIG. 1 is a diagram showing a state in which a circuit for conducting soft turn-off is connected to a gate driver circuit of an insulated gate bipolar transistor (IGBT) according to an exemplary embodiment of the present invention;

FIG. 2 is a graph showing results obtained by measuring current Ic flowing in emitter and collector terminals of a PNP transistor, based on a voltage applied to base and emitter terminals of the PNP transistor;

FIG. 3 is a graph showing a state in which the circuit according to the exemplary embodiment of the present invention is actually installed in a driver circuit of the IGBT;

FIG. 4 is a graph showing that the voltage at the gate terminal of the IGBT is slowly dropped as the circuit according to the exemplary embodiment of the present invention is operated;

FIG. 5 is a diagram showing a conventional circuit for protecting an IGBT, using an integrated circuit;

FIG. 6 is a diagram showing a conventional circuit for implementing soft turn-off, using RC discharge; and

FIG. 7 is a graph showing a change in voltage between collector and emitter terminals of the IGBT as soft turn-off is implemented.

It should be understood that the appended drawings are not necessarily to scale, presenting a somewhat simplified representation of various preferred features illustrative of the basic principles of the invention. The specific design features of the present invention as disclosed herein, including, for example, specific dimensions, orientations, locations, and shapes will be determined in part by the particular intended application and use environment.

In the figures, reference numbers refer to the same or equivalent parts of the present invention throughout the several figures of the drawing.

### DETAILED DESCRIPTION

Hereinafter reference will now be made in detail to various embodiments of the present invention, examples of which are illustrated in the accompanying drawings and described below. While the invention will be described in conjunction with exemplary embodiments, it will be understood that present description is not intended to limit the invention to those exemplary embodiments. On the contrary, the invention is intended to cover not only the exemplary embodiments, but also various alternatives, modifications, equivalents and other embodiments, which may be included within the spirit and scope of the invention as defined by the appended claims.

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, combustion, plug-in hybrid electric vehicles, hydrogen-powered vehicles, fuel cell vehicles, and other alternative fuel vehicles (e.g., fuels derived from resources other than petroleum).

Additionally, it is understood that the below methods are executed by circuitry components.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

Unless specifically stated or obvious from context, as used herein, the term “about” is understood as within a range of normal tolerance in the art, for example within 2 standard deviations of the mean. “About” can be understood as within 10%, 9%, 8%, 7%, 6%, 5%, 4%, 3%, 2%, 1%, 0.5%, 0.1%, 0.05%, or 0.01% of the stated value. Unless otherwise clear from the context, all numerical values provided herein are modified by the term “about.”

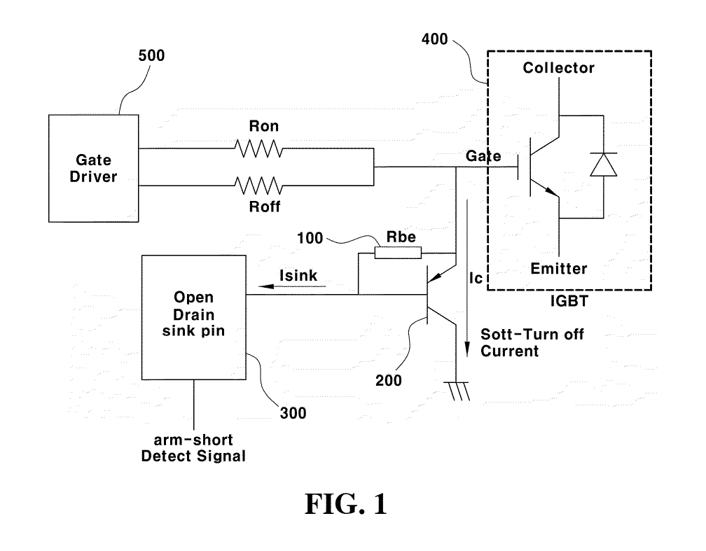

FIG. 1 is a diagram showing a state in which a circuit for conducting soft turn-off is connected to a gate driver circuit of an insulated gate bipolar transistor (IGBT) according to an exemplary embodiment of the present invention. The circuit according to the exemplary embodiment of the present invention may include a PNP transistor 200, a resistor 100, and a sink pin 300 which can apply a low signal to a base terminal of the PNP transistor 200. Low signals refer to a sink or source current controlled by H/L (high/low) of a CPU or Micom. For example, in the present invention, a gate current may be released to PNP Transistor (i.e., a layer of N-doped semiconductor between two layers of P-doped material) being controlled by a base terminal current. Therefore, low signal should be understood by those skilled in the art as the current controlling the base of the PNP transistor. The circuit according to the exemplary embodiment of the present invention may have the resistor 100 provided between emitter and base terminals of the PNP transistor 200, so that electric charges accumulated in a gate terminal of an IGBT 400 are slowly discharged out to a ground. Since the resistor 100 is provided between the emitter and base terminal of the PNP transistor 200, the resistor 100 may abbreviated as resistor Rbe. A collector terminal of the PNP transistor 200 may be connected to the ground, as well. Also, the sink pin 300 may be connected to the base terminal of the PNP transistor 200.

The sink pin 300 may be configured with an open drain type sink pin. In addition, the sink pin 300 may be configured with a general purpose input output (GPIO) port of a general microcomputer (MICOM) which includes at least a processor and memory that are configured to execute and store programmable logic thereon respectively to carry out control of the sink pin. A complex programmable logic device (CPLD) may be used as the general MICOM. However, a means for providing the sink pin 300 is not limited thereto, and another equivalent means may be used as long as it applies a low signal to the base terminal of the PNP transistor 200. Here, the low signal may be a value corresponding to ‘high’ of the voltage used in general electronic equipments, or may be a value corresponding to a binary number of ‘0’.

Furthermore, the programmable logic of the present invention may be embodied as non-transitory computer readable media on a computer readable medium containing executable program instructions executed by a processor, controller or the like. Examples of the computer readable mediums include, but are not limited to, ROM, RAM, compact disc (CD)-ROMs, magnetic tapes, floppy disks, flash drives, smart cards and optical data storage devices. The computer readable recording medium can also be distributed in network coupled computer systems so that the computer readable media is stored and executed in a distributed fashion, e.g., by a telematics server or a Controller Area Network (CAN).

An operating process of the circuit according to the exemplary embodiment of the present invention will be described as follows.

Generally, a gate driver 500 can abruptly cut off a gate-off signal at the gate terminal of the IGBT 400 through a gate-off resistor R_{off}. However, when the gate-off signal is abruptly cut off, the conduction current flowing between collector and emitter terminals of the IGBT 400 is suddenly changed. This may cause a sudden increase in voltage between the collector and emitter terminals of the IGBT 400. Thus, in order to solve such a problem, there is required a technique for slowly removing electric charges at the gate terminal of the IGBT 400. The technique may be referred to as a soft turn-off technique.

In order to slowly remove the electric charges at the gate terminal of the IGBT 400, the circuit according to the exemplary embodiment of the present invention may have a configuration in which the emitter terminal of the PNP transistor 200 is connected to the gate terminal of the IGBT 400 and the collector terminal of the PNP transistor 200 is connected to the ground.

First, if s an overcurrent situation occurs in which current is excessively applied to a load of the IGBT 400 or an arm short situation in which current is simultaneously conducted to arms of the IGBT so that the arms of the IGBT are short-circuited, an arm short detect signal or the like may be applied to the MICOM having the open drain type sink pin 300. The MICOM receiving the arm short detect signal may drop the voltage of the sink pin 300 to lower value than a previously applied value (i.e., “low).

If the voltage of the sink pin 300 is dropped to ‘low’, current Isink flows through the sink pin 300, which causes a voltage to be formed through the resistor 100 connected to the base and emitter terminals of the PNP transistor 200. Thus, the voltage applied to the emitter and base terminals of the PNP transistor 200 is biased, so that the PNP transistor 200 is turned on.

The voltage applied to the base and emitter terminals of the PNP transistor 200 may determine current Ic slowing in the emitter and collector terminals of the PNP transistor 200. That is, as the voltage applied to the base and emitter terminals of the PNP transistor 200 is increased, the current Ic may be increased. As the voltage applied to the base and emitter terminals of the PNP transistor 200 is decreased, the current Ic may be increased. Thus, as the resistance of the resistor 100 connected to the base and emitter terminals of the PNP transistor 200 is freely selected, it is possible to easily determine the time when the electric charges accumulated in the gate terminal of the IGBT 400 is discharged out to the ground.

In the PNP transistor 200 of the circuit according to the exemplary embodiment of the present invention, the emitter terminal may be referred to as a current inflow terminal, and the collector terminal may be referred to as a current outflow terminal. In addition, the base terminal of the PNP transistor 200 may be referred to as a current control terminal.

As such, the circuit according to the exemplary embodiment of the present invention can be implemented with only the open drain type sink pin. Thus, an exclusive driver integrated circuit (IC) can be implemented with only the GPIO port provided in the general MICOM or CPLD. Accordingly, it is possible to provide a circuit for conducting soft turn-off, which is operated independently on a gate IC.

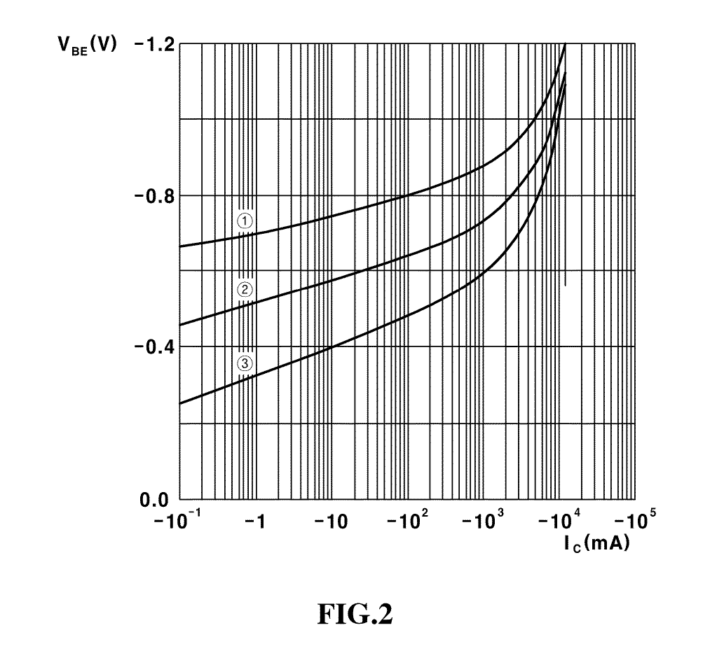

FIG. 2 is a graph showing results obtained by measuring the current Ic flowing in the emitter and collector terminals of the PNP transistor 200, based on a voltage applied to the base and emitter terminals of the PNP transistor 200.

Corresponding experiments were performed at different temperatures. In FIG. 2, 1). is a graph showing a result obtained by measuring the current Ic at about −55° C., 2). is a graph showing a result obtained by measuring the current Ic at about 25° C., and 3). is a graph showing a result obtained by measuring the current Ic at about 100° C. Through the graph of FIG. 2, it can be seen that as the voltage applied to the base and emitter terminals of the PNP transistor 200 is increased, the current Ic flowing through the emitter and collector terminals of the PNP transistor 200 is increased.

Through the graph of FIG. 2, it can also be seen that although the voltage applied to the base and emitter terminals of the PNP transistor 200 as the temperature is increased, the current Ic flowing between the emitter and collector terminals of the PNP transistor 200 is further increased.

Thus, through the experiments of FIG. 2, it can be seen that the voltage applied to the base and emitter terminals of the PNP transistor 200 in the range of −55° C. to 100° C., which is a range where the circuit according to the exemplary embodiment is used, thereby controlling the current flowing in the emitter and collector terminals of the PNP transistor 200.

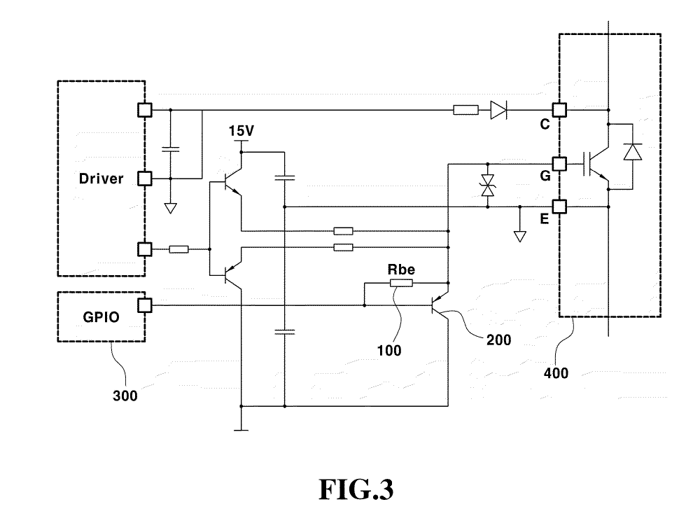

FIG. 3 is a graph showing a state in which the circuit according to the exemplary embodiment of the present invention is actually installed in a driver circuit of the IGBT 400. The circuit according to the exemplary embodiment of the present invention is not necessarily installed in the circuit of FIG. 3, however, and any driving circuit can be utilized. The circuit according to the exemplary embodiment of the present invention may be modified as long as it has a configuration in which the emitter terminal of the PNP transistor 200 is connected to the gate terminal of the IGBT 400 and the collector terminal of the PNP transistor 200 is connected to the ground. Thus, the circuit according to the exemplary embodiment of the present invention can be provided in the gate driver circuit of the IGBT 400.

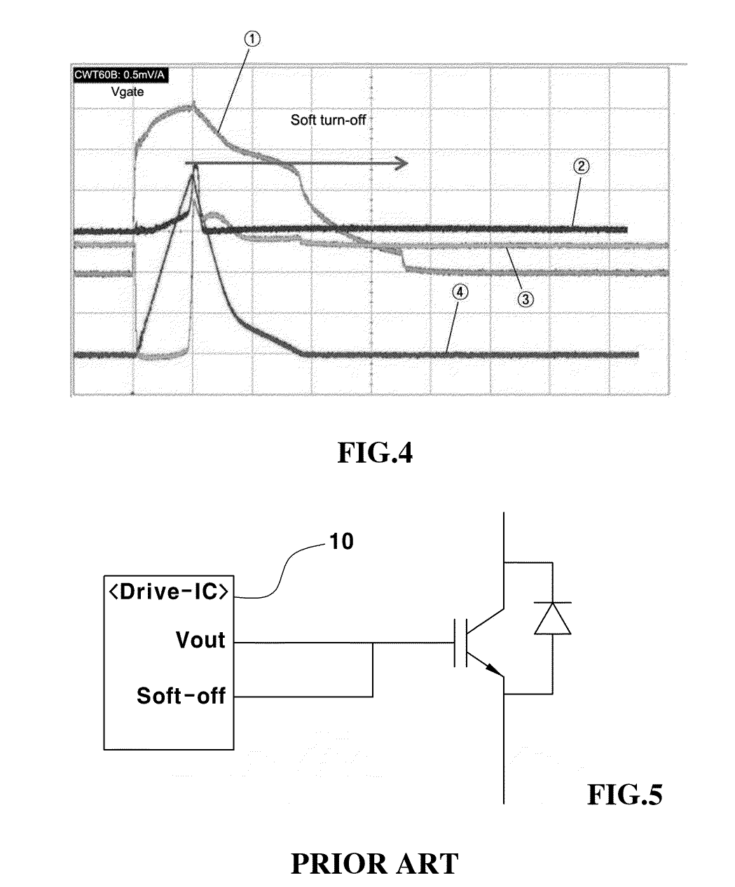

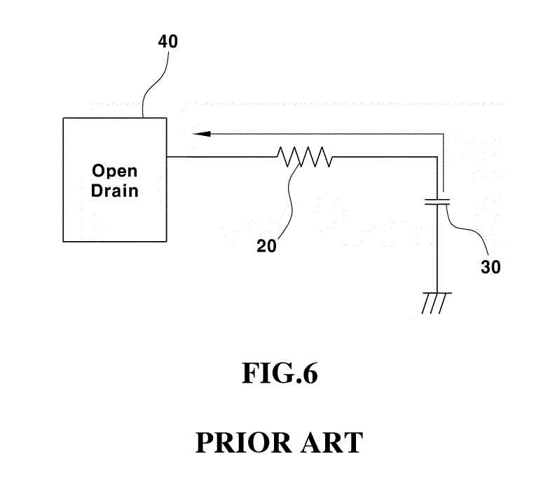

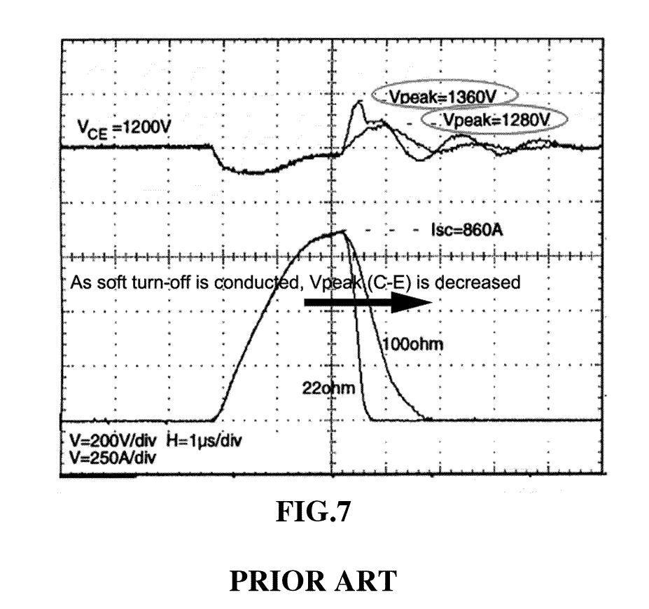

FIG. 4 is a graph showing that the voltage at the gate terminal of the IGBT 400 is slowly dropped as the circuit according to the exemplary embodiment of the present invention is operated. In FIG. 4, 1). is a graph showing a voltage at the gate terminal of the IGBT 400, 2). is a graph showing a voltage at the base terminal of the PNP transistor 200, 3). is a graph showing a desaturation voltage, and 4). is a graph showing a voltage between the collector and emitter terminals of the PNP transistor 200.

Through the graph of FIG. 4, it can be seen that as the voltage at the gate terminal of the IGBT 400 is slowly dropped, the circuit according to the exemplary embodiment of the present invention is preferably operated even in a situation where the gate-off signal is quickly cut off due to the occurrence of a breakdown situation of the IGBT 400.

As described above, the circuit for conducting soft turn-off has advantages as follows.

First, since the circuit for conducting soft turn-off can be implemented via using only the open drain type sink pin, the circuit can be implemented with the GPIO port provided in the general MICOM or CPLD without using any exclusive driver IC. Thus, it is possible to provide a circuit for conducting soft turn-off, which is independent on a gate IC.

Second, since the amount of sink current is controlled by a fixed bias voltage during turn-off, it is possible to provide a circuit having soft turn-off characteristics.

Third, the sink path of soft turn-off is provided using the PNP transistor, so that the voltage of the PNP transistor can be greater than the sink current internal voltage of a general IC, thereby providing a more stable solution than conventional circuits.

The invention has been described in detail with reference to exemplary embodiments thereof. However, it will be appreciated by those skilled in the art that changes may be made in these embodiments without departing from the principles and spirit of the invention, the scope of which is defined in the appended claims and their equivalents.

What is claimed is:

1. A circuit for conducting soft turn-off, the circuit comprising:
a second semiconductor switching device having a current inflow terminal connected to a current control terminal of a first semiconductor switching device, and a current outflow terminal connected to a ground;
a resistor having a first terminal connected to the current inflow terminal of the second semiconductor switching device, and a second terminal connected to a current control terminal of the second semiconductor switching device; and
a sink pin configured to apply a value lower than a previously applied value to the current control terminal of the second semiconductor switching device.

2. The circuit of claim 1, wherein the second semiconductor switching device is a PNP transistor, the current control terminal of the second semiconductor switching device is a base terminal, the current inflow terminal of the second semiconductor switching device is an emitter terminal, and the current outflow terminal of the second semiconductor switching device is a collector terminal.

3. The circuit of claim 1, wherein the sink pin is an open drain type sink pin or a general purpose input output (GPIO) port.

4. The circuit of claim 1, wherein the first semiconductor switching device is an insulated gate bipolar transistor (IGBT), and the current control terminal of the first semiconductor switching device is a gate terminal.

5. A method for conducting soft turn-off, the method comprising:
changing, by a processor, by a an output of a sink pin into a value that is lower than a previously applied value when a failure occurs in a first semiconductor switching device;
discharging current flow to the sink pin through a resistor between a current inflow terminal and a current outflow terminal of a second semiconductor switching device, wherein a voltage is generated through the resistor; and
discharging the current accumulated in the current control terminal of the first semiconductor switching device to a ground through the current inflow terminal and the current outflow terminal of the second semiconductor switching device as the voltage is generated through the resistor.

6. The method of claim 5, wherein the first semiconductor switching device is an IGBT, and the current control terminal of the first semiconductor switching device is a gate terminal,
wherein the second semiconductor switching device is a PNP transistor, the current control terminal of the second semiconductor switching device is a base terminal, the current inflow terminal of the second semiconductor switching device is an emitter terminal, and the current outflow terminal of the second semiconductor switching device is a collector terminal, and
wherein the sink pin is an open drain type sink pin or a general purpose input output (GPIO) port.

7. A circuit installed in a vehicle for conducting soft turn-off, the circuit comprising:
a second switch having a current inflow terminal connected to a current control terminal of a first switch, and a current outflow terminal connected to a ground;
a resistor having a first terminal connected to the current inflow terminal of the first switch, and a second terminal connected to a current control terminal of the second switch; and
a sink pin configured to apply a value lower than a previously applied value to the current control terminal of the second switch when the first switch has failed.

8. The circuit of claim 7, wherein the second switch is a PNP transistor, the current control terminal of the second semiconductor switching device is a base terminal, the current inflow terminal of the second semiconductor switching device is an emitter terminal, and the current outflow terminal of the second semiconductor switching device is a collector terminal.

9. The circuit of claim 7, wherein the sink pin is an open drain type sink pin or a general purpose input output (GPIO) port.

10. The circuit of claim 7, wherein the first semiconductor switching device is an insulated gate bipolar transistor (IGBT), and the current control terminal of the first semiconductor switching device is a gate terminal.
